(19) United States
(12) Patent Application Publication
(10) Pub. No.: US 2011/0168231 A1
(43) Pub. Date: Jul. 14, 2011

(54) PHOTOVOLTAIC CELL ARRAY WITH MECHANICAL UNCOUPLING OF THE CELLS FROM THE CARRIER THEREOF

(75) Inventor: Laurent D'abrigeon, Theoule (FR)

(73) Assignee: THALES, Neuilly-sur-Seine (FR)

(21) Appl. No.: 13/120,856

(22) PCT Filed: Sep. 23, 2009
(86) PCT No.: PCT/EP2009/062296

§ 371 Date: Mar. 31, 2011

(30) Foreign Application Priority Data
Sep. 26, 2008 (FR) 0805308

(51) Int. Cl. H01L 31/042

(52) U.S. Cl. 136/244

(57) ABSTRACT

A solution is provided for reducing the mechanical coupling of the photovoltaic array of the solar generator in relation to the latter's support substrate. Indeed, the photovoltaic cell is very slender (a few tens of microns) and very fragile. When the latter is glued onto a substrate, it undergoes all the geometric deformations due to vibrations but especially to thermo-elastic effects, possibly leading to the breakage of the cells. The cell is fastened via a flexible system making it possible to decouple the cell from the deformations of the substrate while ensuring sufficient radiative coupling of the cell toward the substrate to avoid heating thereof in flight and loss of effectiveness thereof. The solution includes using photovoltaic cells with high-emissivity rear face (rear use of a metallization or kaptoning of the Ge or Ag substrate) that is fixed with the aid of Velcro onto the substrate.

The present invention pertains to an array of photovoltaic cells with support substrate with mechanical decoupling of the cells of the array with respect to their rigid support substrate, such arrays generally serving in the production of solar generator panels to ensure the electrical power supply for spacecraft, and in particular for satellites.

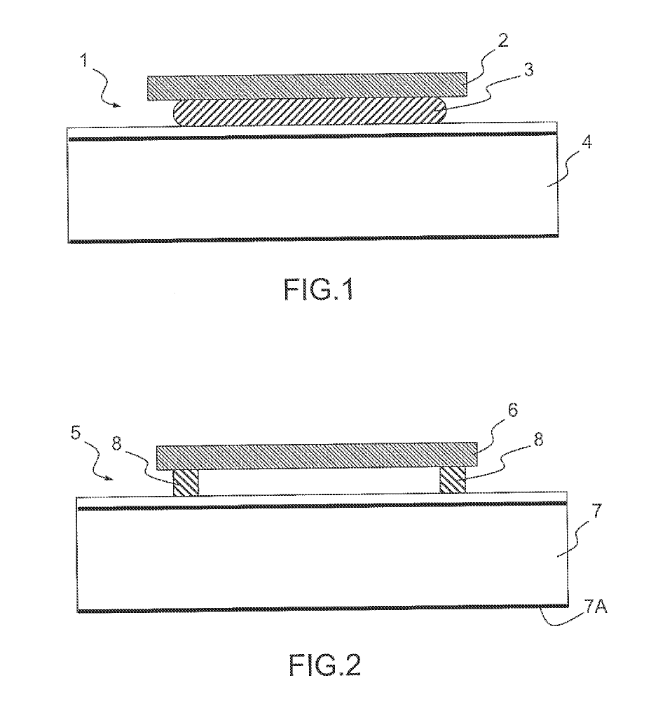

Shown diagrammatically in FIG. 1 is an exemplary embodiment of a prior art photovoltaic element 1 (also termed “Covered Interconnected Cell” or “Solar Cell Assembly”), this element forming part of an array comprising from a few hundred to several tens of thousands of such elements depending on the powers required in orbit. This element 1 comprises a photovoltaic cell 2 fastened by way of a layer 3 of adhesive to a rigid substrate 4 common to several cells.

In an array of this type, the photovoltaic cells are very fragile because of their small thickness and very sensitive to the deformations which are customarily imposed on them by their gluing onto a rigid substrate. Indeed, the substrate is generally a sandwich with carbon skins the thermo-elastic stability of which is limited: the unidirectionally strengthened zones may wrinkle or else the skins may deform into cups above the mesh of the honeycomb (phenomenon termed “Telegraphing”).

Moreover, fixing by gluing raises the problem of the possible repair of the cells, which is then laborious, since it is necessary to very delicately scratch off the insulant, which is for example Kapton™, and which is applied to the substrate. The operation of removing a cell from its substrate may be estimated at about a day's work.

The gluing of the cells onto the substrate tends to deform the cells. One way of mechanically decoupling the cell from the substrate consists in thickening the glue layer, but this significantly increases the total mass and introduces a risk of anarchic degassing of the glue that may even lead to the exploding of the cell (phenomenon termed “Pop-off”).

Flexible cell fastening systems (such as “filament”, “thin film”, etc.) pose a problem of heavy technological rupture of the architecture of the solar generators but also the introduction of problems affecting the AOCS (“Attitude on Orbit Control System”) for steering the carrier satellite when the fastening of the cells is done on flexible wings.

The idea of fastening the cell onto its support substrate in a mechanically decoupled manner without worrying about the thermal aspect is not appropriate, since the mechanical decoupling causes the conductive coupling to be lost and absolutely must be replaced with radiative coupling. In the case of loss of cell-substrate thermal coupling, the cell will rise in temperature and lose the majority of its effectiveness.

The subject of the present invention is an array of elements with photovoltaic cells and with rigid support substrate, exhibiting mechanical decoupling between each cell of this array and the support substrate, while ensuring good mutual thermal conduction, this array being used in particular in the guise of solar generator for supplying electrical power for satellites.

The photovoltaic array in accordance with the invention is characterized in that each photovoltaic element of the array is fastened to the substrate by way of a self-adhesive and easily resoluble flexible fastening device, the posterior face of each cell and the anterior face of the substrate comprising a layer improving their thermal radiation qualities.

The present invention will be better understood on reading the detailed description of an embodiment, taken by way of nonlimiting example and illustrated by the appended drawing in which:

FIG. 1, already mentioned hereinabove, is a sectional schematic view of a prior art solar panel photovoltaic array element,

FIG. 2 is a sectional schematic view of a solar panel photovoltaic array element in accordance with the invention,

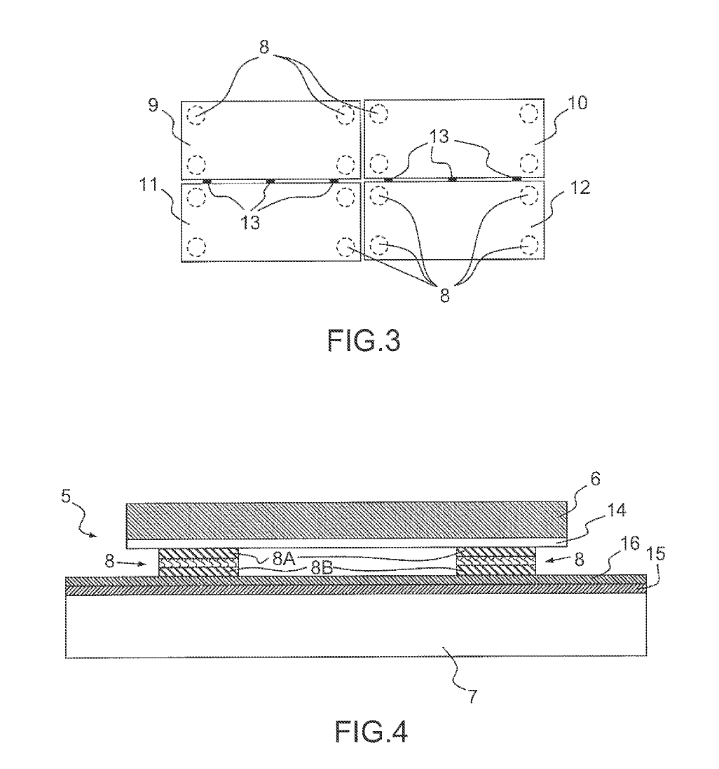

FIG. 3 is a plan view of four adjacent cells of a solar panel photovoltaic array in accordance with the invention, and

FIG. 4 is a sectional schematic view of a solar panel photovoltaic array element in accordance with the invention more detailed than that of FIG. 2.

The invention proposes a solution for reducing the mechanical coupling of the photovoltaic array of the solar generator in relation to the latter's support substrate. Indeed the photovoltaic cell is very slender (a few tens of microns thick) and very fragile. When the latter is glued to the substrate, it undergoes all the geometric deformations due to vibrations, but especially to thermo-elastic effects, possibly leading to the breakage of the cells. The idea consists in fastening the cell via a flexible system making it possible to decouple the cell with respect to the deformed parts of the substrate while ensuring sufficient radiative coupling of the cell toward the substrate to avoid heating thereof in flight and loss of effectiveness thereof. The solution consists in using photovoltaic cells with high-emissivity rear face (rear use of a grid or kaptoning of the Ge or Ag substrate) that is fixed with the aid of Velcro onto the substrate.

The photovoltaic element 5 shown diagrammatically in FIG. 2 comprises a photovoltaic cell 6 fastened onto a corresponding zone of a substrate 7 (the latter being common to several cells) by way of Velcro™ tie pads 8, or similar self-adhesive and easily resoluble flexible fastening devices. The details of producing these various elements are described hereinbelow with reference to FIGS. 3 and 4. The posterior face 7A of the substrate 7 is treated in a manner known per se, and its front face remains covered with an insulating film of Kapton type of a grade endowed with high emissivity so as to ensure good thermal radiative conduction toward the support (not represented) on which this substrate is fastened. The coefficient ε of thermal emissivity obtained by virtue of this film is for example about 0.6 to 0.9.

In the plan view of FIG. 3 are represented four adjacent rectangular cells 9 to 12 forming part of a photovoltaic solar panel (the other cells of which are not represented). Each of the cells 9 to 12 is fastened to the support substrate, in the manner detailed hereinbelow, with the aid of four Velcro pads 8 each disposed under a corner of the cell. The cells of one and the same column are linked together by electrical interconnections 13.

Detailed in FIG. 4 are the various constituents of the photovoltaic element 5 of FIG. 2. The photovoltaic cell 6 proper is for example of the conventional Si or AsGa type. It is coated on its posterior face (that opposite its support) with a self-adhesive Kapton™ foil 14, having for example a thickness of about 50 μm. As a variant, this coating may be a metallization layer, for example a layer of silver. The coefficient ε of thermal emissivity of Kapton is about 0.61 whereas that of silver is about 0.05. Kapton is advantageously used because it is less expensive than a metallization, although it is not as good thermally, this making it possible moreover not to change the process for manufacturing the existing cells on the market.

The substrate face 7 opposite the cell 6 is a carbon skin 15, itself covered with a Kapton layer 16, the substrate 7 being in general of the “honeycomb” type with an objective of high thermal conductivity between its front face and its rear face.

The parts 8A of Velcro pads secured to the cell 6 are fastened to the layer 14 of the latter by gluing, and the corresponding parts 8B of Velcro pads secured to the substrate 7 are fastened by gluing onto the layer 16 of the substrate, the Velcro advantageously being of the self-adhesive type.

Thus, by virtue of the invention, the radiative thermal coupling between the photovoltaic cells and the substrate is ensured by using contemporary photovoltaic cells and by depositing a Kapton film which is self-adhesive, on the rear face. Moreover, the use of cells with a gluing zone located at the rear instead of gluing over the whole surface makes it possible to have on the rear face of the cell the same (good) emissivity as for the front face of the cell.

1. An array of photovoltaic cells comprising a rigid support substrate, wherein each photovoltaic element of the array is fastened to the substrate by way of a self-adhesive and easily resoluble flexible fastening device, a posterior face of each cell and an anterior face of the substrate comprising a layer improving their thermal radiation qualities.

2. The array as claimed in claim 1, wherein the flexible fastening device consists of Velcro™ pads of which one part is secured to the cell, and an other is secured to the substrate.

3. The array as claimed in claim 2, wherein each cell is fastened to the substrate by four pads each disposed under a corner of the surface.

4. The array as claimed in claim 1, wherein said layer improving the thermal radiation qualities is Kapton™ or a metallization.

5. The array as claimed in claim 1, forming part of a spacecraft solar generator.
